(19) United States
(12) Patent Application Publication
(10) Pub. No.: US 2012/0052641 A1
(43) Pub. Date: Mar. 1, 2012

(54) Methods of Manufacturing MOS Transistors

(76) Inventors: Hye-Lan Lee, Hwaseong-si (KR); Sangjin Hyun, Suwon-si (KR); Yugyun Shin, Seongnam-si (KR); Hongbae Park, Gyeyang-gu (KR); Huyong Lee, Seoul (KR); Hyung-seok Hong, Ansan-si (KR)

(21) Appl. No.: 13/217,871

(22) Filed: Aug. 25, 2011

(30) Foreign Application Priority Data
Sep. 1, 2010 (KR) 10-2010-0085650

(51) Int. Cl. H01L 21/336

(52) U.S. Cl. 438/270; 438/589; 257/E21.41; 257/E21.409

(57) ABSTRACT

Methods of manufacturing a MOS transistor are provided. The methods may include forming first and second trenches. The methods may further include forming first metal patterns within portions of the first and second trenches. The methods may additionally include removing the first metal patterns from the second trench while at least portions of the first metal patterns remain within the first trench. The methods may also include forming a second metal layer within the first and second trenches, the second metal layer formed on the first metal patterns within the first trench.

### CROSS-REFERENCE TO RELATED APPLICATIONS

This U.S. non-provisional patent application claims priority under 35 U.S.C. §119 to Korean Patent Application No. 10-2010-0085650, filed on Sep. 1, 2010, the disclosure of which is hereby incorporated by reference in its entirety.

### BACKGROUND

The present disclosure generally relates to methods of manufacturing semiconductor devices and, more particularly, to methods of manufacturing metal-oxide-semiconductor (MOS) transistors.

MOS transistors have been widely used as switching elements. Gate electrodes of MOS transistors have sometimes been made of a metallic material, which may have improved electrical conductivity compared with polysilicon. According to the type of channel below a gate electrode, MOS transistors may be classified into NMOS transistors and PMOS transistors. Gate electrodes of an NMOS transistor and a PMOS transistor may be made of different metal materials such that the NMOS transistor and the PMOS transistor have different threshold voltages.

### SUMMARY

According to some embodiments, methods of manufacturing a MOS transistor may include providing a substrate including first and second active regions. The methods may also include forming dummy gate stacks on the first and second active regions. The methods may further include forming source/drain regions within the first and second active regions adjacent sidewalls of the dummy gate stacks. The methods may additionally include forming a mold insulating layer on the source/drain regions. The methods may also include removing the dummy gate stacks to form a first trench on the first active region and to form a second trench on the second active region. The methods may further include forming a gate insulating layer in the first and second trenches. The methods may additionally include forming first metal patterns within portions of the first and second trenches. The methods may also include removing the first metal patterns from the second trench while at least portions of the first metal patterns remain within the first trench. The methods may further include forming a second metal layer within the first and second trenches to form a first gate electrode on the first active region and to form a second gate electrode on the second active region, the second metal layer formed on the first metal patterns within the first trench.

In some embodiments, each of the first metal patterns may include a first work function metal layer having a higher work function than the second metal layer.

In some embodiments, the first work function metal layer may include titanium nitride.

In some embodiments, the methods may further include, after removing the first metal patterns from the second trench, forming a second work function metal layer having a lower work function than the first work function metal layer on the first metal pattern within the first trench, and within the second trench.

In some embodiments, the second work function metal layer may include titanium aluminum.

In some embodiments, forming the first metal patterns may include forming a first metal layer and a dummy filler layer in the first trench and the second trench and on the mold insulating layer. Forming the first metal patterns may also include planarizing the dummy filler layer and the first metal layer to expose a surface of the mold insulating layer. Forming the first metal patterns may further include removing a portion of the first metal layer from between the mold insulating layer and the dummy filler layer to form the first metal pattern at lower portions of the first and second trenches. Forming the first metal patterns may additionally include removing the dummy filler layer from the first and second trenches.

In some embodiments, the first metal layer may be formed by chemical vapor deposition or atomic layer deposition.

In some embodiments, forming the first metal patterns may include forming a first metal layer that is substantially planar in lower portions of the first and second trenches and on a surface of the mold insulating layer, the first metal layer having a protrusion at upper portions of the first and second trenches such that the first metal layer is thicker at the protrusion than in the lower portions of the first and second trenches. Forming the first metal patterns may also include removing the protrusion of the first metal layer. Forming the first metal patterns may further include forming a dummy filler layer within the first and second trenches and on the mold insulating layer. Forming the first metal patterns may additionally include planarizing the dummy filler layer and the first metal layer to expose a surface of the mold insulating layer. Forming the first metal patterns may also include removing the dummy filler layer from the first and second trenches.

In some embodiments, the methods may further include, after planarizing the dummy filler layer and the first metal layer, removing portions of the first metal layer from between the mold insulating layer and the dummy filler layer.

In some embodiments, the first metal layer may be formed by physical vapor deposition.

In some embodiments, the physical vapor deposition may include sputtering.

In some embodiments, removing the first metal patterns from the second trench may include forming a sacrificial oxide layer on the first metal patterns within the first trench and the second trench. Removing the first metal patterns may also include forming a photoresist pattern on the sacrificial oxide layer within the first trench. Removing the first metal patterns may further include removing the sacrificial oxide layer and the first metal patterns from the second trench. Removing the first metal patterns may additionally include, after removing the first metal patterns from the second trench, removing the photoresist pattern and the sacrificial oxide layer from the first trench.

According to some embodiments, MOS transistors may include first and second active regions defined by an isolation layer. MOS transistors may also include source/drain impurity regions in the first and second active regions. MOS transistors may further include a mold insulating layer on the source/drain impurity regions. MOS transistors may additionally include a gate insulting layer on portions of the first and second active regions between the source/drain impurity regions. MOS transistors may also include a first gate electrode including a U-shaped first metal pattern on the gate insulating layer on the first active region, a second metal layer on the U-shaped first metal pattern, and a third metal layer on the second metal layer. MOS transistors may further include a second gate electrode including the second and third metal layers on the gate insulating layer on the second active region, the second and third metal layers on the second active region having different shapes from the second and third metal layers on the first active region.

In some embodiments, the first metal pattern may include titanium nitride.

In some embodiments, the second metal layer may include titanium aluminum having a lower work function than the titanium nitride.

According to some embodiments, methods of manufacturing a MOS transistor may include forming a mold insulating layer on first and second dummy gates on first and second regions of a substrate. The methods may also include removing the first and second dummy gates to form first and second trenches between portions of the mold insulating layer. The methods may further include forming a first metal layer within the first and second trenches. The methods may additionally include removing portions of the first metal layer from the first and second trenches to form first metal patterns in the first and second trenches, the first metal patterns having a higher work function than the second metal layer. The methods may also include removing the first metal patterns from the second trench while at least portions of the first metal patterns remain within the first trench. The methods may additionally include forming a second metal layer within the first and second trenches, the second metal layer formed on the first metal patterns within the first trench, and the second metal layer having a shape within the first trench that is different from a shape of the second metal layer within the second trench.

In some embodiments, forming the first metal patterns may include forming the first metal layer to be substantially planar in lower portions of the first and second trenches and on a surface of the mold insulating layer, the first metal layer having a protrusion at upper portions of the first and second trenches such that the first metal layer is thicker at the protrusion than in the lower portions of the first and second trenches. Forming the first metal patterns may also include removing the protrusion of the first metal layer from sidewalls of the first and second trenches. Forming the first metal patterns may further include forming a dummy filler layer within the first and second trenches and on the mold insulating layer. Forming the first metal patterns may additionally include planarizing the dummy filler layer and the first metal layer to expose a surface of the mold insulating layer. Forming the first metal patterns may also include removing the dummy filler layer from the first trench and the second trench.

In some embodiments, the methods may further include, after planarizing the dummy filler layer and the first metal layer, removing portions of the first metal layer from between the mold insulating layer and the dummy filler layer to form the first metal patterns, the first metal patterns having narrower portions on opposing sidewalls of each of the first and second trenches than on a bottom surface of the first and second trenches.

In some embodiments, the methods may further include forming a third metal layer on the second metal layer within the first and second trenches, the third metal layer having a shape within the first trench that is different from a shape of the third metal layer within the second trench.

In some embodiments, the methods may further include, before forming the first metal layer, forming a gate insulating layer within the first and second trenches, and forming first and second metal barrier layers on the gate insulating layer within the first and second trenches.

### BRIEF DESCRIPTION OF THE DRAWINGS

The above and other features and advantages of the disclosure will become more apparent by describing in detail example embodiments thereof with reference to the attached drawings in which:

FIGS. 1 to 21 are cross-sectional views illustrating a method for manufacturing a MOS transistor according to some embodiments.

FIG. 22 includes cross-sectional views of PMOS transistors.

FIG. 23 is a graphic diagram illustrating gate line resistances depending on variation in gate widths of the PMOS transistors shown in FIG. 22.

FIGS. 24 to 34 are cross-sectional views illustrating a method for manufacturing a MOS transistor according to some embodiments.

### DETAILED DESCRIPTION

Example embodiments are described below with reference to the accompanying drawings. Many different forms and embodiments are possible without deviating from the spirit and teachings of this disclosure and so the disclosure should not be construed as limited to the example embodiments set forth herein. Rather, these example embodiments are provided so that this disclosure will be thorough and complete, and will convey the scope of the disclosure to those skilled in the art. In the drawings, the sizes and relative sizes of layers and regions may be exaggerated for clarity. Like reference numbers refer to like elements throughout.

Example embodiments are described herein with reference to cross-section illustrations that are schematic illustrations of idealized example embodiments (and intermediate structures). As such, variations from the shapes of the illustrations as a result, for example, of manufacturing techniques and/or tolerances, are to be expected. Thus, example embodiments may not be construed as limited to the particular shapes of regions illustrated herein but may be construed to include deviations in shapes that result, for example, from manufacturing.

The terminology used herein is for the purpose of describing particular embodiments only and is not intended to be limiting of the embodiments. As used herein, the singular foams “a,” “an,” and “the” are intended to include the plural forms as well, unless the context clearly indicates otherwise. It will be further understood that the terms “comprises,” “comprising,” “includes,” and/or “including,” when used herein, specify the presence of stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein the term “and/or” includes any and all combinations of one or more of the associated listed items.

It will be understood that, although the terms first, second, etc. may be used herein to describe various elements, these elements should not be limited by these terms. These terms are only used to distinguish one element from another. Thus, a first element could be termed a second element without departing from the teachings of the present embodiments.

Unless otherwise defined, all terms (including technical and scientific terms) used herein have the same meaning as commonly understood by one of ordinary skill in the art to which these embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A method for manufacturing a MOS transistor according to some embodiments may include a method for replacing a dummy gate electrode of polysilicon with a metal gate electrode.

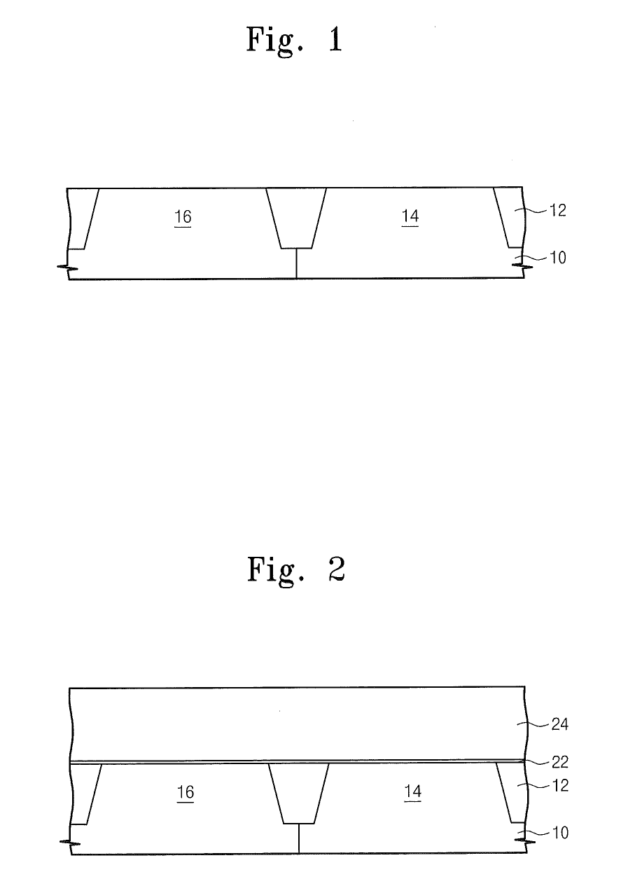

FIGS. 1 to 21 are cross-sectional views illustrating a method for manufacturing a MOS transistor according to some embodiments.

Referring to FIG. 1, a first well and a second well may be formed in a first active region 14 and a second active region 16, respectively, which may be defined by isolation layers 12 on a substrate 10. The first well may be formed by implanting impurities of first conductivity type (hereinafter referred to as “first-type impurities”). The first-type impurities may include a donor such as phosphorous (P) or arsenic (As). For example, the first-type impurities may be implanted into the first well at an energy of about 100 KeV to about 300 KeV and a concentration of about 1×10¹³ EA/cm³ to about 1×10¹⁶ EA/cm³. The second well may be formed by implanting impurities of second conductivity type (hereinafter referred to as “second-type impurities”) opposite to the first conductivity type. The second-type impurities may include an acceptor such as boron (B). For example, the second-type impurities may be implanted into the second well at an energy of about 70 KeV to about 200 KeV and a concentration of about 1×10¹³ EA/cm³ to about 1×10¹⁶ EA/cm³. The isolation layers 12 may be formed after formation of the first well and the second well. The isolation layers 12 may include a silicon oxide layer formed in a trench, which may be formed by removing the substrate 10 to a predetermined depth, by means of plasma-enhanced chemical vapor deposition (PECVD).

Referring to FIG. 2, a dummy gate insulating layer 22 and a dummy gate electrode 24 may be stacked on the substrate 10. The dummy gate insulating layer 22 may include silicon oxide (SiO₂). For example, the dummy gate insulating layer 22 may be formed to a thickness ranging from about 30 to about 200 angstroms by means of chemical vapor deposition (CVD), atomic layer deposition (ALD) or rapid thermal processing (RTP). The dummy gate electrode 24 may include polysilicon formed by means of CVD.

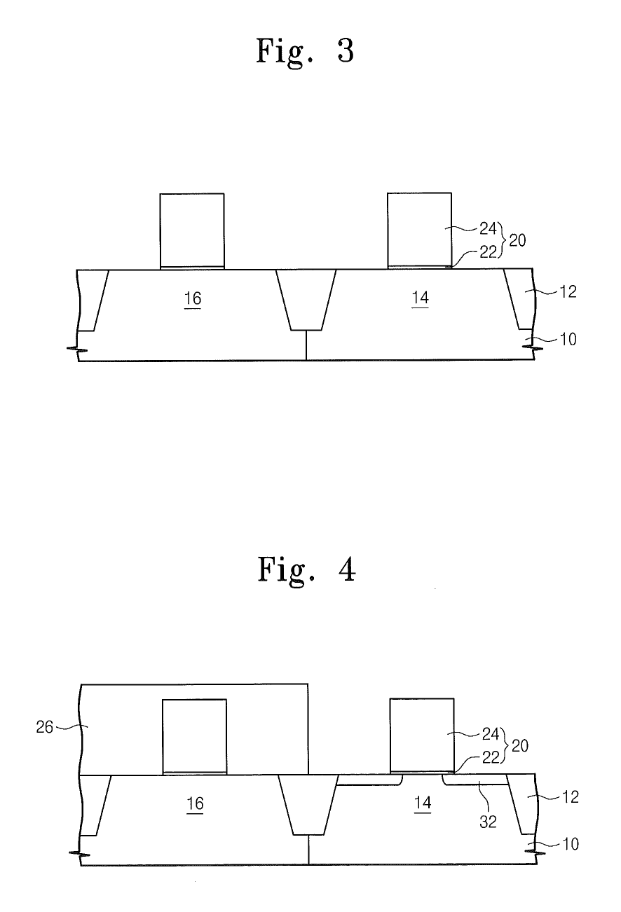

Referring to FIG. 3, dummy gate stacks 20 including the dummy gate insulating layers 22 and the dummy gate electrodes 24 may be formed on the first active region 14 and the second active region 16. The dummy gate stacks 20 may be patterned by a photolithography process and an etching process. For example, a first photoresist pattern (not shown) may be formed on the dummy gate electrodes 24. Next, the dummy gate electrodes 24 and the dummy gate insulating layers 22 may be sequentially etched using the first photoresist pattern as an etch mask.

Referring to FIG. 4, a second photoresist pattern 26 may be formed to cover the second active region 16. A lightly doped drain (LDD) 32 may be formed on the first active region 14 by using the second photoresist pattern 26 in the second active region 16 and the dummy gate stack 20 in the first active region 14 as etch masks. Second-type impurities may be implanted into the first active region 14. For example, the second-type impurities may be implanted at an energy of about 1 KeV to about 20 KeV and a concentration of about 1×10¹³ EA/cm³ to about 1×10¹⁶ EA/cm³. Thereafter, the second photoresist pattern 26 may be removed.

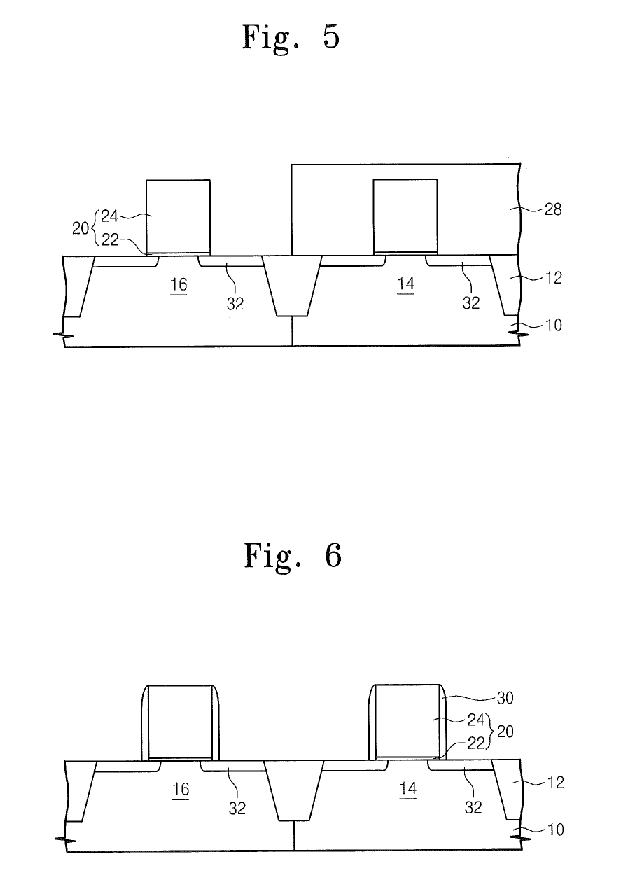

Referring to FIG. 5, a third photoresist pattern 28 may be formed to cover the first active region 14. An LDD 32 may be formed on the second active region 16 by using the third photoresist pattern 28 in the first active region 14 and the dummy gate stack 20 in the second active region 16 as etch masks. In this case, first-type impurities may be implanted into the second active region 16. The first-type impurities may be implanted at an energy of about 5 KeV to about 30 KeV and a concentration of about 1×10¹³ EA/cm³ to about 1×10¹⁶ EA/cm³. LDDs 32 may be formed in the first active region 14 and the second active region 16 to substantially the same depth and may be formed to extend to substantially the same distance beneath a portion of the dummy gate stacks 20. After forming the LDD 32 on the second active region 16, the third photoresist pattern 28 may be removed.

Referring to FIG. 6, spacers 30 may be formed on sidewalls of the dummy gate stacks 20. Each of the spacers 30 may be formed in a self-aligned manner. For example, each of the spacers 30 may include a silicon nitride layer formed by means of CVD. The self-aligned manner may include a dry etching process performed to anisotropically remove a silicon nitride layer covering the dummy gate stacks. Thus, the spacers 30 may include the silicon nitride remaining on the sidewalls of the dummy gate stacks 20 from the dry etching process.

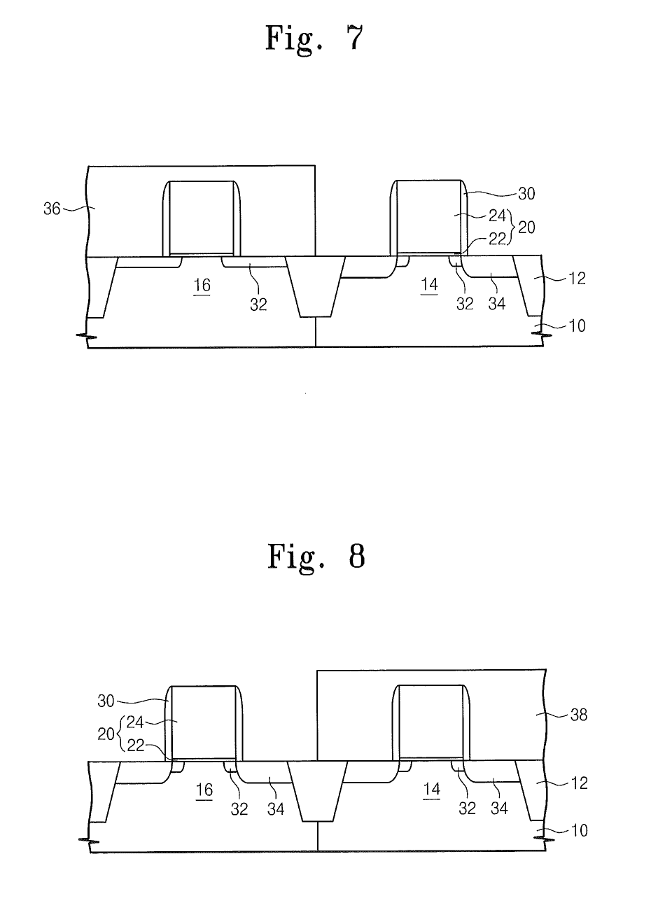

Referring to FIG. 7, a fourth photoresist pattern 36 may be formed to cover the second active region 16. A source/drain impurity region 34 may be formed on the first active region 14 by using the fourth photoresist pattern 36, the dummy gate electrode 24 in the first active region 14, and the spacers 30 as etch masks. The source/drain impurity region 34 may include second-type impurities. For example, the second-type impurities may be implanted into the first active region 14 at an energy of about 10 KeV to about 40 KeV and a concentration of about 1×10¹⁶ EA/cm³ to about 1×10¹⁷ EA/cm³. After forming the source/drain impurity region 34 on the first active region 14, the fourth photoresist pattern 36 formed on the second active region 16 may be removed.

Referring to FIG. 8, a fifth photoresist pattern 38 may be formed to cover the first active region 14. A source/drain impurity region 34 may be formed on the second active region 16 by using the fifth photoresist pattern 38, the dummy gate electrode 24 in the second active region 16, and the spacers 30 as etch masks. For example, first-type impurities may be implanted into the second active region 16 at an energy of about 10 KeV to about 50 KeV and a concentration of about 1×10¹⁶ EA/cm³ to about 1×10¹⁷ EA/cm³. Source/drain impurity regions 34 may be formed on the first active region 14 and the second active region 16 to substantially the same thickness. Thereafter, the fifth photoresist pattern 38 formed on the substrate 10 may be removed.

Although not shown in FIG. 8, the source/drain impurity regions 34 may be formed by removing portions of the first and second active regions 14 and 16 adjacent opposite sides of the dummy gate stacks 20 and filling the removed portions with epitaxial silicon germanium (e-SiGe) including impurities of their respective conductivity types.

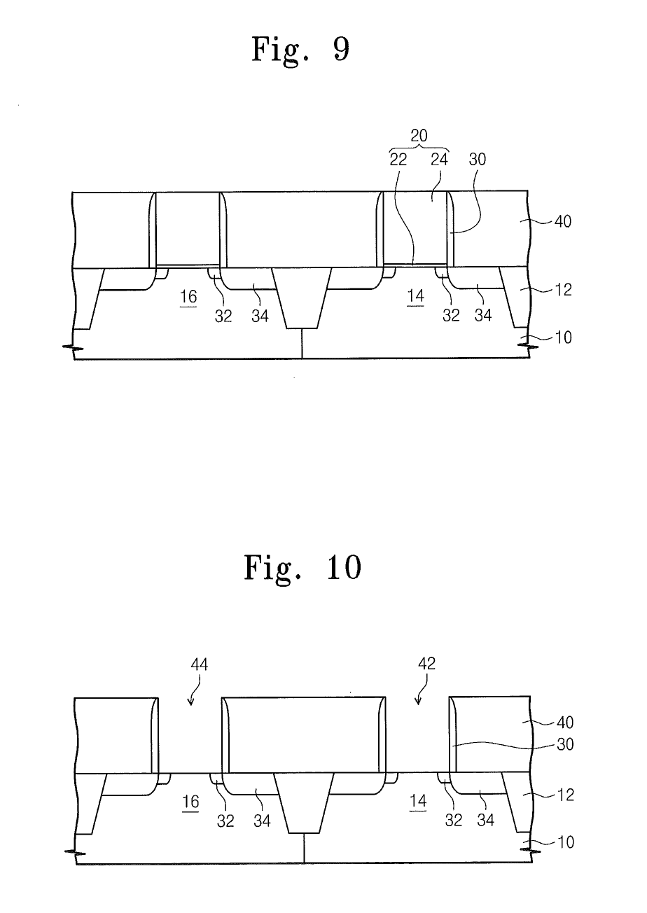

Referring to FIG. 9, a mold insulating layer 40 may be formed on the isolation layers 12 and the source/drain impurity regions 34. The mold insulating layer 40 may include a silicon oxide layer. In some embodiments, the mold insulating layer 40 may be formed on the isolation layers 12, the source/drain impurity regions 34, and the dummy gate stacks 20. The mold insulating layer 40 may be formed by means of low-pressure CVD (LPCVD) or plasma-enhanced CVD (PECVD). The mold insulating layer 40 may be planarized to expose the dummy gate electrodes 24 (e.g., to expose a surface of the dummy gate electrodes 24 that is substantially coplanar with a surface of the planarized mold insulating layer 40). Planarization of the mold insulating layer 40 may be accomplished by means of chemical mechanical polishing (CMP) or an etchback process.

Referring to FIG. 10, the dummy gate stacks 20 on the first active region 14 and the second active region 16 may be removed to form a first trench 42 and a second trench 44, respectively. Removal of the dummy gate stacks 20 may be accomplished by means of wet etching or dry etching. The mold insulating layer 40 and the spacers 30 may be used as etch masks during removal of the dummy gate stacks 20.

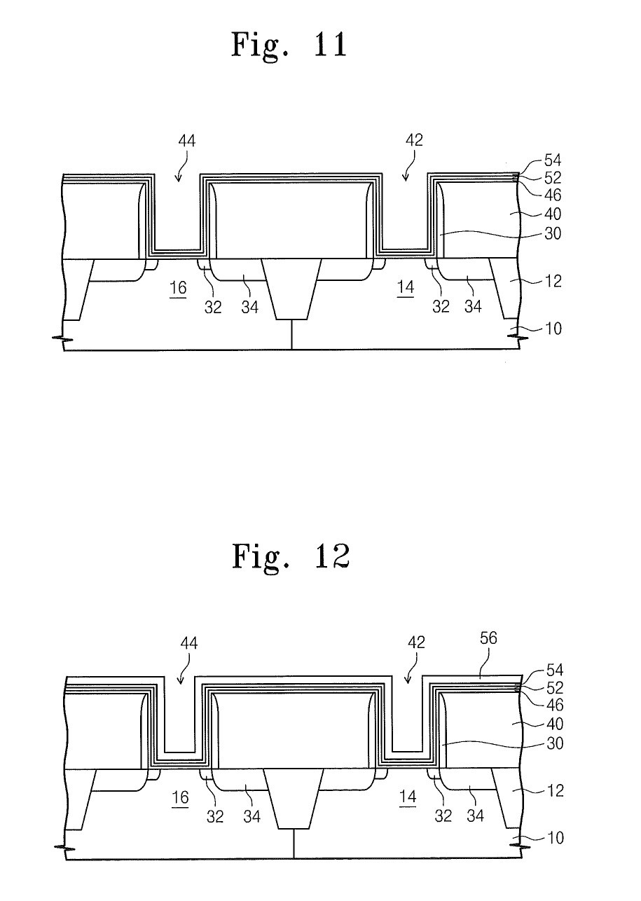

Referring to FIG. 11, a gate insulating layer 46, a first barrier metal layer 52, and a second barrier metal layer 54 may be provided (e.g., formed and/or stacked) on substantially the entire surface of the substrate 10. For example, the gate insulating layer 46, the first barrier metal layer 52, and the second barrier metal layer 54 may be provided in the first trench 42 and the second trench 44. The gate insulating layer 46 may include a high-k dielectric material. For example, the gate insulating layer 46 may include at least one of hafnium oxide (HfO₂), hafnium silicon oxide (HfSiO), hafnium silicon oxynitride (HfSiON), hafnium oxynitride (HfON), hafnium aluminum oxide (HfAlO), hafnium lanthanum oxide (HfLaO), zirconium oxide (ZrO₂), tantalum oxide (TaO₂), zirconium silicon oxide (ZrSiO), lanthanum oxide (La₂O₃), praseodymium oxide (Pr₂O₃), dysprosium oxide (Dy₂O₃), BST oxide (BaₓSr₁₋ₓTiO₃), and PZT oxide (Pb(ZrₓTi₁₋ₓ)O₃).

The first barrier metal layer 52 may protect the gate insulating layer 46. The first barrier metal layer 52 and the second barrier metal layer 54 may be formed on the gate insulating layer 46 by an in-situ process. The second barrier metal layer 54 may protect the first barrier metal layer 52 and the gate insulating layer 46 from a subsequent etching process. The first barrier metal layer 52 and the second barrier metal layer 54 may include metal layers that are substantially identical to each other or different from each other. The first barrier metal layer 52 and the second barrier metal layer 54 may include a binary metal nitride such as titanium nitride (TiN), tantalum nitride (TaN), tungsten nitride (WN), and hafnium nitride (HfN); or a ternary metal nitride such as titanium aluminum nitride (TiAlN), tantalum aluminum nitride (TaAlN), and hafnium aluminum nitride (HfAlN). For example, the first barrier metal layer 52 may include titanium nitride (TiN), and the second barrier metal layer 54 may include tantalum nitride (TaN).

Referring to FIG. 12, a first work function metal layer 56 may be formed on the second barrier metal layer 54. The first work function metal layer 56 may include a metallic material such as titanium (Ti), tantalum (Ta), hafnium (Hf), tungsten (W), and molybdenum (Mo). Also, the first work function metal layer 56 may include a nitride, carbide, silicon nitride, or silicide containing the metallic material. For example, the first work function metal layer 56 may include titanium nitride (TiN), which may be formed by means of CVD or ALD. In some embodiments, the first work function metal layer 56 may include platinum (Pt), rubidium (Ru), iridium oxide (IrO), or rubidium oxide (RuO). The first work function metal layer 56 may be formed to substantially the same thickness, not only over the mold insulating layer 40, but also on a bottom and a sidewall of the first trench 42. The first work function metal layer 56 may be formed to a thickness ranging from about 50 angstroms to about 100 angstroms.

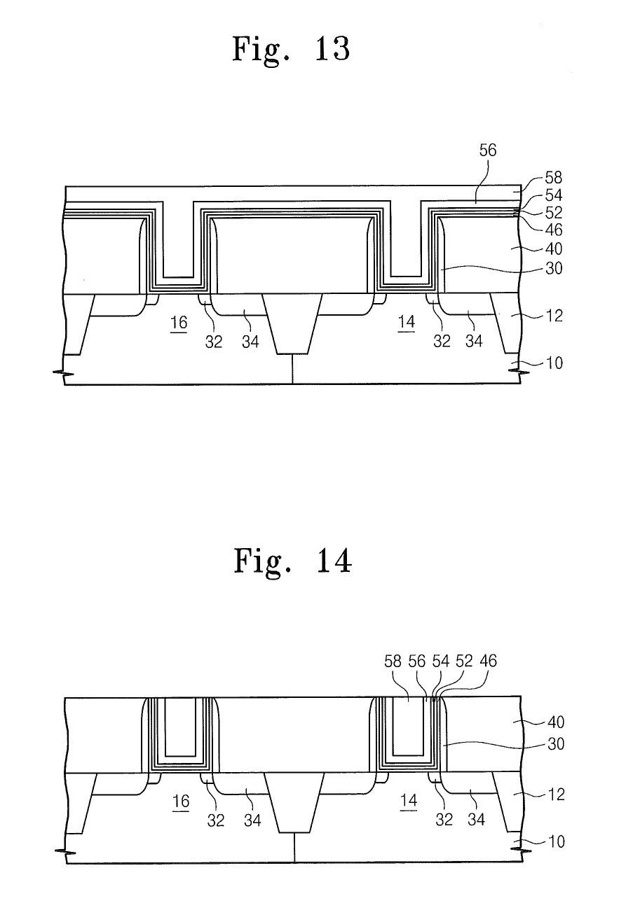

Referring to FIG. 13, a dummy filler layer 58 may be formed on the first work function metal layer 56. The dummy filler layer 58 may be formed in the first and second trenches 42 and 44 and on the mold insulating layer 40. The dummy filler layer 58 may include an organic (i.e., carbon-containing) compound. The organic compound may be formed on substantially the entire surface of the substrate 10 by means of spin coating, for example. The dummy filler layer 58 may substantially fill the first trench 42 and the second trench 44. In addition, the dummy filler layer 58 may be formed of silicon oxide or polysilicon. The silicon or polysilicon may be formed by means of CVD. The mold insulating layer 40 (e.g., oxide) may have a higher density than the silicon oxide of the dummy filler layer 58.

Referring to FIG. 14, the dummy filler layer 58, the first work function metal layer 56, the first barrier metal layer 52, the second barrier metal layer 54, and the gate insulating layer 46 may be planarized to expose the mold insulating layer 40 (e.g., to expose a surface of the mold insulating layer 40 that is substantially coplanar with a surface of the planarized dummy filler layer 58 and/or the first work function metal layer 56). Planarization of the dummy filler layer 58 and the first work function metal layer 56 may be accomplished by means of an etchback or a CMP. For example, the dummy filler layer 58 of an organic compound may be planarized by an etchback such as a dry etch. In addition, the dummy filler layer 58 of silicon oxide or polysilicon may be planarized by means of a CMP. After planarizing the dummy filler layer 58, the dummy filler layer 58 and first work function metal layer 56 may remain only in the first trench 42 and the second trench 44 (e.g., only within opposing sidewalls of each of the first trench 42 and the second trench 44).

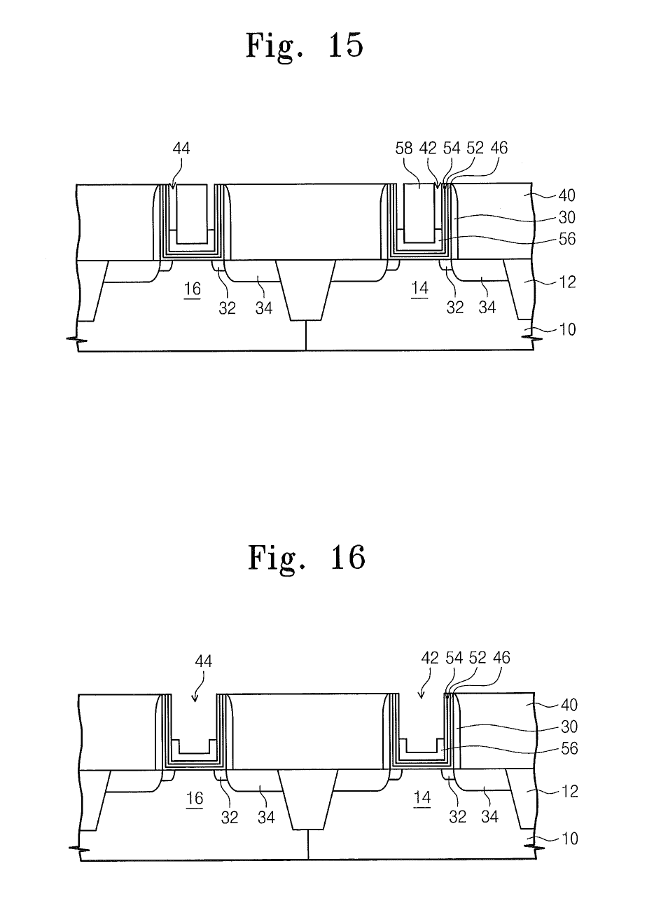

Referring to FIG. 15, portions of the first work function metal layer 56 may be removed from the first trench 42 and the second trench 44. For example, portions of the first work function metal layer 56 between the mold insulating layer 40 and the dummy filler layer 58 may be recessed. Recession of the first work function metal layer 56 may be accomplished by means of a dry etch or a wet etch having an etch selectivity of greater than about two to one with respect to the dummy filler layer 58 and the mold insulating layer 40. First work function metal layers 56 may remain adjacent/beneath bottom surfaces and sidewalls of the first and second trenches 42 and 44. For example, remaining portions of the first work function metal layer 56 may be between the dummy filler layer 58 and the substrate 10 in the first and second trenches 42 and 44. Additionally, remaining portions of the first work function metal layer 56 may be along sidewalls of the dummy filler layer 58 in the first and second trenches 42 and 44. The first work function metal layers 56 may be first work function metal patterns that are formed in the first and second trenches 42 and 44, and each of the first work function metal patterns may have a ␣-shaped section. For example, the first work function metal layers 56 may be recessed on the sidewalls of the first and second trenches 42 and 44 to a depth (e.g., from a surface of the substrate 10) of about 450 angstroms in a thickness ranging from about 100 angstroms to about 300 angstroms.

Referring to FIG. 16, the dummy filler layers 58 may be removed from within the first trench 42 and the second trench 44. The remaining portions of the first work function metal layers 56 may be exposed within the first trench 42 and the second trench 44 by removing the dummy filler layers 58. The dummy filler layers 58 may be removed by means of ashing, a dry etch, or a wet etch. For example, dummy filler layers 58 of an organic compound may be removed by means of ashing. In addition, dummy filler layers 58 of silicon oxide or polysilicon may be removed by means of a dry etch or a wet etch. The second barrier metal layers 54 may protect the first barrier metal layers 52 and the gate insulating layers 46 from an etch gas or an etchant during removal of the dummy filler layers 58.

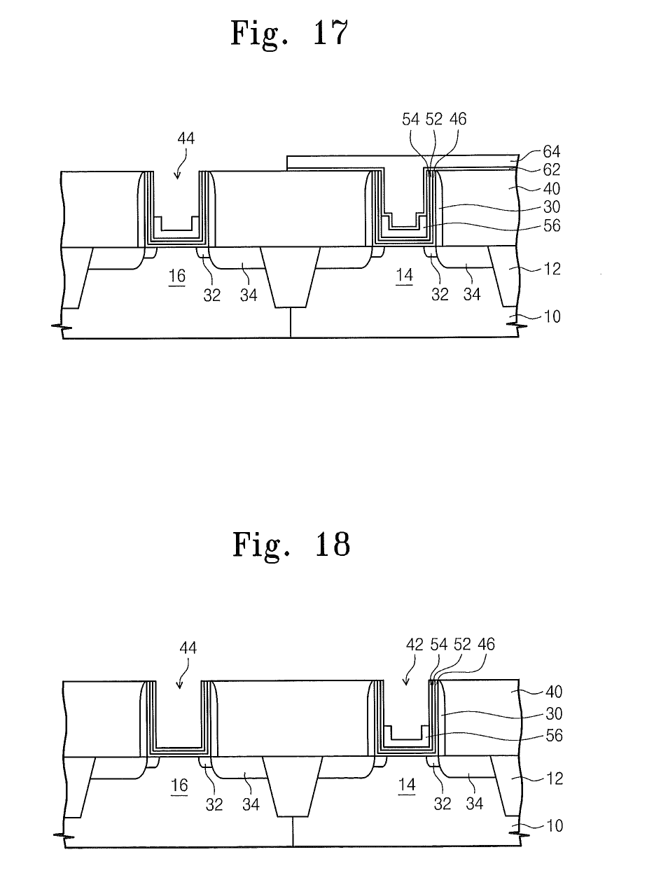

Referring to FIG. 17, a sacrificial oxide layer 62 and a sixth photoresist pattern 64 may be formed on a portion of a surface of the mold insulating layer 40 and within the first trench 42. The sacrificial oxide layer 62 and the sixth photoresist pattern 64 may be formed to expose the first work function metal layer 56 within the second trench 44. The sacrificial oxide layer 62 may be formed on substantially the entire surface of the substrate 10, including the first trench 42 and the second trench 44. The sixth photoresist pattern 64 may be formed on a portion of a surface of the mold insulating layer 40 and within the first trench 42 by means of a photolithography process for a photoresist (not shown) formed on the sacrificial oxide layer 62. The portion of the sacrificial oxide layer 62 that is exposed by the sixth photoresist pattern 64 may be removed by means of a dry etch or a wet etch. The sacrificial oxide layer 62 may enhance adhesion between the first work function metal layer 56 on the first active layer 14 and the sixth photoresist pattern 64, as well as between the second barrier metal layer 54 on the first active layer 14 and the sixth photoresist pattern 64.

Referring to FIG. 18, the first work function metal layer 56 may be removed from within the second trench 44 while the first work function metal layer 56 remains in the first trench 42. The first work function metal layer 56 within the second trench 44 may be removed by a dry etch or a wet etch using the sixth photoresist pattern 64 as an etch mask. Afterwards, the sacrificial oxide layer 62 and the sixth photoresist pattern 64 may be removed.

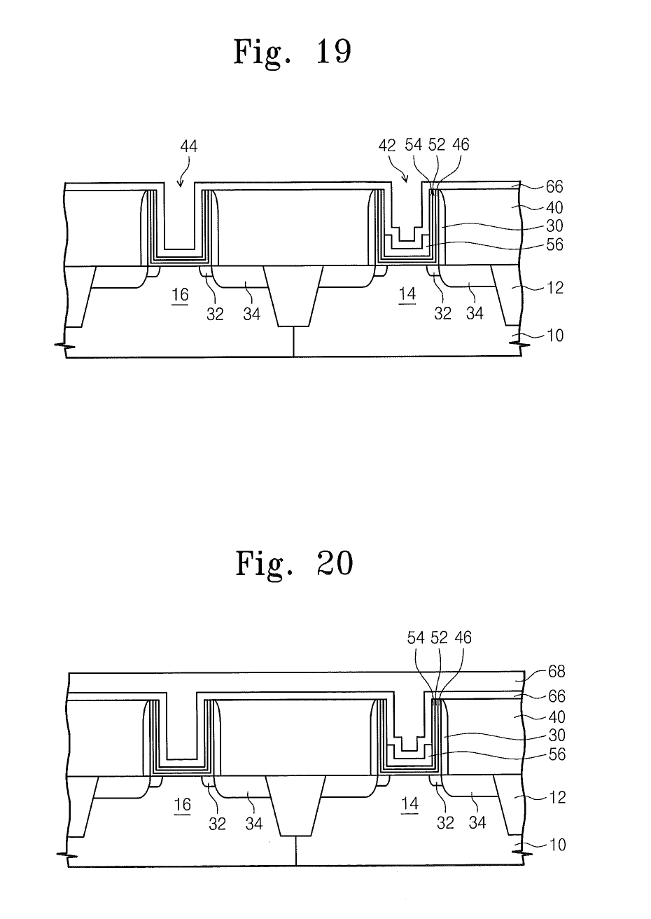

Referring to FIG. 19, a second work function metal layer 66 may be formed within the first and second trenches 42 and 44 and on substantially the entire surface of the mold insulating layer 40. The second work function metal layer 66 may have a lower work function than the first work function metal layer 56. For example, the second work function metal layer 66 may include titanium aluminum having a work function ranging from about 4.0 eV to about 4.2 eV. The titanium aluminum may be formed by means of CVD or sputtering.

Referring to FIG. 20, a third metal layer 68 may be formed within the first and second trenches 42 and 44 and on the mold insulating layer 40. The third metal layer 68 may be formed by means of physical vapor deposition (PVD) or CVD. The third metal layer 68 may include at least one of low-resistance metals such as aluminum (Al), tungsten (W), titanium (Ti), and tantalum (Ta). The third metal layer 68 may be formed within the first trench 42 substantially without formation of voids. The second work function metal layer 66 may include a diffusion metal layer through which low-resistance metallic components of the third metal layer 68 are diffused into the second barrier metal layer 54. Accordingly, the second work function metal layer 66 may be formed by an annealing process for the second barrier metal layer 54 and the third metal layer 68.

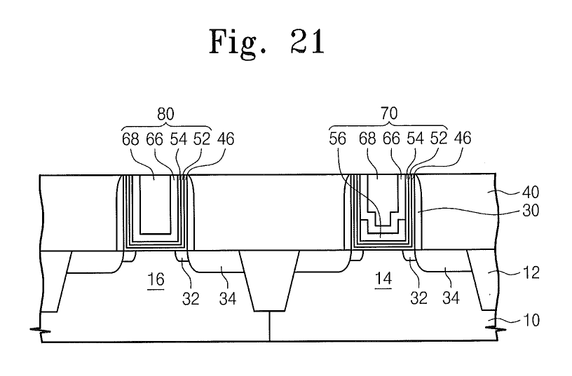

Referring to FIG. 21, the third metal layer 68 may be planarized to expose the mold insulating layer 40 (e.g., to expose a surface of the mold insulating layer 40 that is substantially coplanar with a surface of the third metal layer 68). A first gate electrode 70 and a second gate electrode 80 may be formed on the first active region 14 and the second active region 16, respectively. The first gate electrode 70 and the second gate electrode 80 may be gate lines extending in a direction that is substantially perpendicular to an arrangement direction of the source/drain impurity regions 34 and/or a surface of the substrate 10. The third metal layer 68 may be planarized by means of CMP or etchback. The first gate electrode 70 and the second gate electrode 80 may be separated through the planarization of the third metal layer 68. The first gate electrode 70 and the second gate electrode 80 may have top surfaces of the same height or almost the same height (e.g., surfaces substantially coplanar with an exposed surface of the mold insulating layer 40). The first gate electrode 70 may include a first barrier metal layer 52, a second barrier metal layer 54, a first work function metal layer 56, a second work function metal layer 66, and a third metal layer 68. The first gate electrode 70 may constitute a PMOS transistor in the first active region 14. The second gate electrode 80 may include a first barrier metal layer 52, a second barrier metal layer 54, a second work function metal layer 66, and a third metal layer 68. The second gate electrode 80 may constitute an NMOS transistor in the second active region 16. The first gate electrode 70 and the second gate electrode 80 may each have a length/height of about 450 angstroms (e.g., from a boundary surface with the substrate 10).

Generally, operation characteristics of an NMOS transistor and a PMOS transistor may be different from each other. In an NMOS transistor, a threshold voltage may decrease when work functions of metal layers on a gate insulating layer 46 are low. The NMOS transistor may include a second gate electrode 80 containing a metallic component of a low work function. The second gate electrode 80 may include a first barrier metal layer 52, a second barrier metal layer 54, a second work function metal layer 66, and a third metal layer 68. The second work function metal layer 66 may include substantially the same metal as the third metal layer 68. Therefore, according to some embodiments, formation of the second work function metal layer 66 may be omitted in the method for manufacturing a MOS transistor.

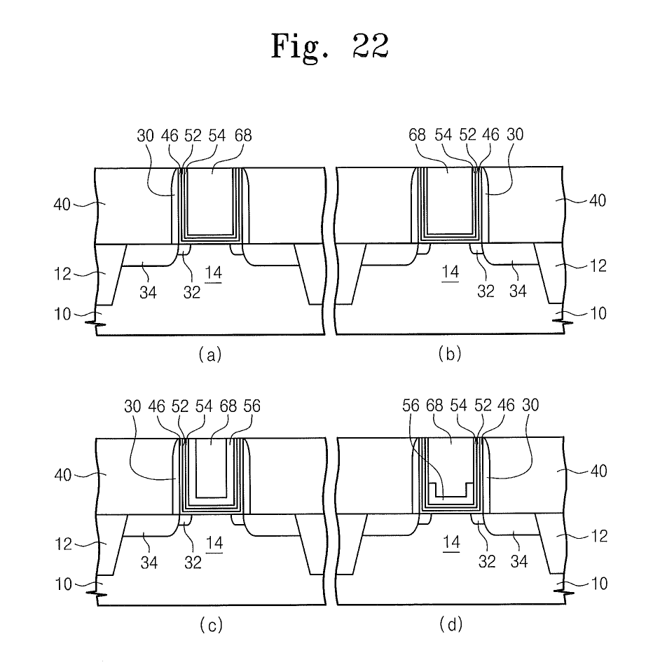

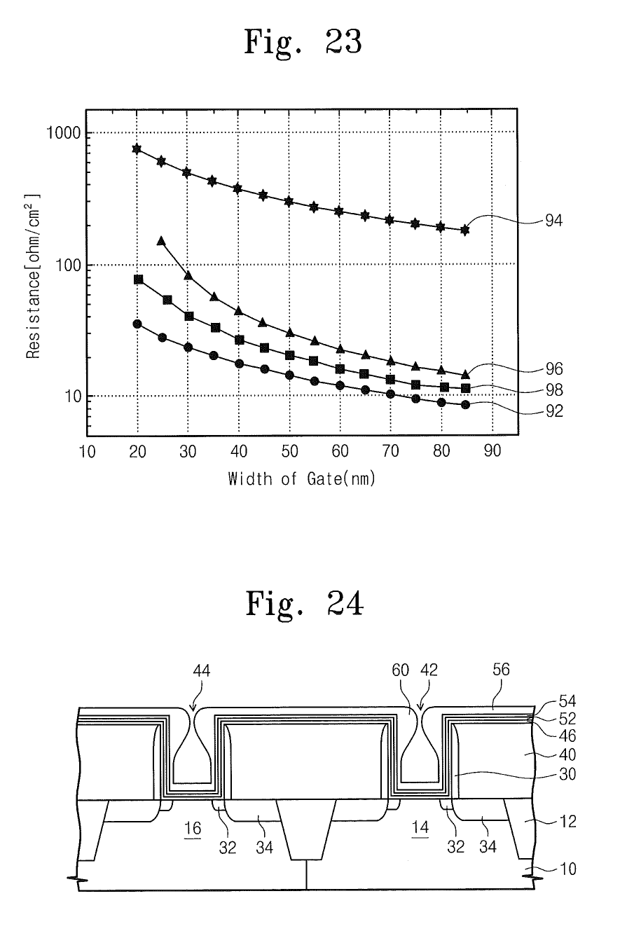

FIG. 22 includes cross-sectional views of PMOS transistors, and FIG. 23 is a graphic diagram illustrating gate line resistances depending on variation in gate widths of the PMOS transistors shown in FIG. 22.

Referring to FIGS. 22 and 23, a resistance of a gate line may increase as width of a gate between source/drain impurity regions 34 decreases. In addition, a resistance of a gate line may vary with the kind and structure (e.g., stacked structure) of a metal layer. For example, a resistance of a gate line having width of about 35 nanometers and height of about 450 nanometers may vary with a material of a metal layer. Referring to FIGS. 22(a) and 23, a gate line (a) of aluminum may have a resistance 92 of about 20 Ohms/cm². The gate line (a) of aluminum may include a first barrier metal layer 52, a second barrier metal layer 54, and a third metal layer 68 within a first trench 42 without including a first work function metal layer 56. The third metal layer 68 may contain aluminum. Given a gate line (a) of aluminum, the gate line resistance 92 may decrease (i.e., may be relatively low), but a threshold voltage may increase (i.e., may be relatively high) at a PMOS transistor because the work function of aluminum is relatively low (about 4.26 eV).

Referring to FIGS. 22(b) and 23, a gate line (b) of titanium nitride may have a resistance 94 of about 400 Ohms/cm². The gate line (b) of titanium nitride may include a first barrier metal layer 52, a second barrier metal layer 54, and a third metal layer 68. The third metal layer 68 may contain titanium nitride. The titanium nitride may have a relatively high work function of about 5.2 eV. Accordingly, given the gate line (b) of titanium nitride, a threshold voltage of a PMOS transistor may decrease, but a gate line resistance 94 may increase (i.e., may be relatively high).

Referring to FIGS. 22(c) and 23, a gate line (c) of aluminum/titanium nitride may have a resistance 96 of about 60 ohms/cm². The gate line (c) of aluminum/titanium nitride may include a first barrier metal layer 52, a second barrier metal layer 54, a first work function metal layer 56, and a third metal layer 68 on a gate insulating layer 46 within a first trench 42. The third metal layer 68 and the first work function metal layer 56 may include aluminum and titanium nitride, respectively. The first work function metal layer 56 may have substantially the same height as the mold insulating layer 40 (e.g., oxide). The first work function metal layer 56 may be formed on not only a lower portion (e.g., closer to the substrate 10), but also an upper portion (e.g., farther from the substrate 10), of the first trench 42.

Referring to FIGS. 22(d) and 23, a gate line (d) of aluminum/recessed titanium nitride may have a more improved resistance 98 than the resistance 96 of the gate line (c) of aluminum/titanium nitride illustrated in FIG. 22(c). For example, the gate line (d) of aluminum/recessed titanium nitride may have a resistance 98 of about 35 Ohms/cm². The gate line (d) of aluminum/recessed titanium nitride may include a first barrier metal layer 52, a second barrier metal layer 54, a first work function metal layer 56, and a third metal layer 68 on a gate insulating layer 46 within a first trench 42. The first work function metal layer 56 may be recessed to be lower (e.g., closer to the substrate 10) than a top surface of a mold insulating layer 40 (e.g., a surface of the mold insulating layer 40 that is substantially coplanar with an exposed surface of the third metal layer 68). The first work function metal layer 56 may only be at a lower portion of the trench 42 (e.g., only on a bottom surface of the first trench 42 and portions of sidewalls of the first trench 42 that are adjacent the substrate 10). The gate line (d) of aluminum/recessed titanium nitride may have substantially the same threshold voltage as the gate line (c) of aluminum/titanium nitride. The gate line (d) of aluminum/recessed titanium nitride may have a lower resistance 98 than the gate line (c) of aluminum/titanium nitride. Additionally, the gate line (d) of aluminum/recessed titanium nitride may decrease a threshold voltage of a PMOS transistor.

Thus, according to methods for manufacturing a MOS transistor according to some embodiments (e.g., as illustrated in FIGS. 22(d) and 23), both (a) a threshold voltage of a PMOS transistor and (b) a resistance of a gate line may be reduced/minimized.

Although not shown, the methods for manufacturing a MOS transistor may be completed/finalized by removing a mold insulating layer 40 on a source/drain impurity region 34 to form a contact hole and by forming a source/drain electrode in the contact hole.

According to some embodiments, methods for manufacturing a MOS transistor may include forming a gate insulating layer 46, a first barrier metal layer 52, and a second barrier metal layer 54 on substantially the entire surface of a substrate 10 (e.g., within the first trench 42 and the second trench 44), as described with reference to FIGS. 1 to 11.

FIGS. 24 to 34 are cross-sectional views illustrating methods for manufacturing a MOS transistor according to some embodiments. In describing FIGS. 24 to 34, duplicate explanations previously described with respect to previous Figures may be omitted for the sake of brevity.

Referring to FIG. 24, a first work function metal layer 56 may be formed on the second barrier metal layer 54. The first work function metal layer 56 may include a metallic material such as titanium (Ti), tantalum (Ta), hafnium (Hf), tungsten (W), and molybdenum (Mo); and a nitride, carbide, silicon nitride, or silicide containing the metallic material. Also, the first work function metal layer 56 may include platinum (Pt), rubidium (Ru), iridium oxide (IrO), or rubidium oxide (RuO). The first work function metal layer 56 may have a work function ranging from about 5.0 eV to about 5.2 eV. The first work function metal layer 56 may be formed within a first trench 42 and a second trench 44 to a thickness ranging from about 50 angstroms to about 100 angstroms.

The first work function metal layer 56 may be formed by means of PVD. The PVD may include a sputtering method, which may be performed to form overhangs 60 (e.g., protrusions) of the first work function metal layer 56 at upper portions or entrances/openings of the first and second trenches 42 and 44. The sputtering method may be a metal deposition method for depositing a high-straightness metallic material on the first work function metal layer 56. A relatively large amount of metallic material may be deposited on an upper portion or a sidewall of the mold insulating layer 40 at upper portions or entrances/openings of the first and second trenches 42 and 44. Accordingly, overhangs 60 may be formed to make the upper portions or the entrances of the first and second trenches 42 and 44 more narrow than portions of the first and second trenches 42 and 44 that are closer to the substrate 10. The overhangs 60 may include a first work function metal layer 56 protruding from the sidewall of the mold insulating layer 40 at the upper portions or the entrances/openings of the first and second trenches 42 and 44. Accordingly, the first work function metal layer 56 formed by means of a sputtering method may include overhangs 60 at the upper portions or the entrances/openings of the first and second trenches 42 and 44. In contrast, the first work function metal layer 56 may be substantially planarly-formed on bottom surfaces (e.g., surfaces closest to the substrate 10) of the first and second trenches 42 and 44 and on a top surface of the mold insulating layer 40.

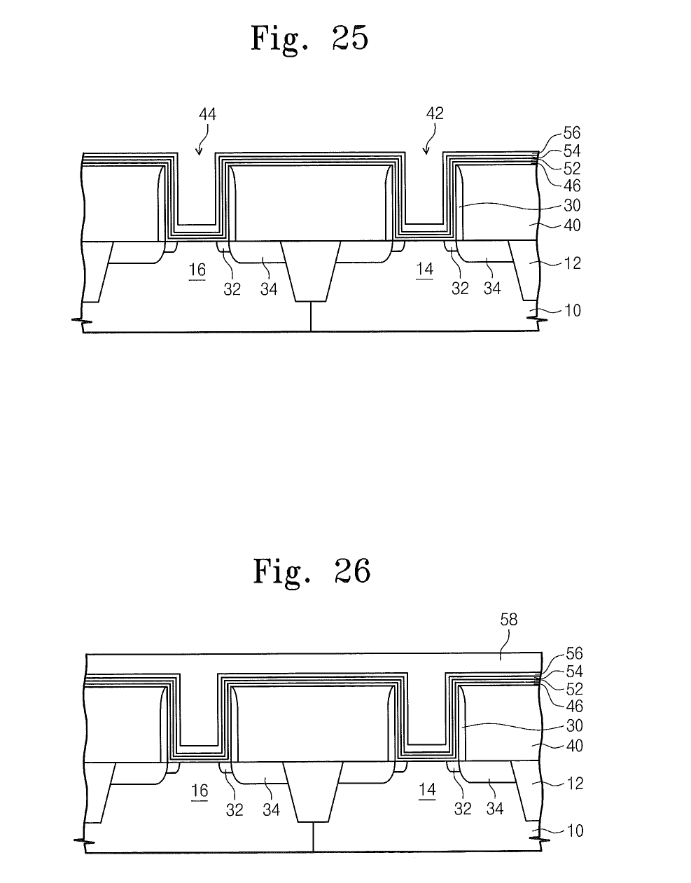

Referring to FIG. 25, the overhangs 60 formed at the upper portions or the entrances/openings of the first and second trenches 42 and 44 may be removed. The overhangs 60 may be removed by, for example, dry etching. Because portions of the first work function metal layer 56 over the mold insulating layer 40 may be etched by dry etching during removal of the overhangs 60, a thickness of the first work function metal layer 56 may decrease. The first work function metal layer 56 at lower portions (e.g., portions closer to the substrate 10) of the first trench 42 and the second trench 44 may not be etched (or may be etched less than upper portions of the first work function metal layer 56) and may thus maintain a substantially constant thickness.

Referring to FIG. 26, a dummy filler layer 58 may be formed on the first work function metal layer 56. The dummy filler layer 58 may be formed in the first and second trenches 42 and 44 and over the mold insulating layer 40. The dummy filler layer 58 may include an organic (i.e., carbon-containing) compound. The organic compound may be formed on substantially the entire surface of the substrate 10 by, for example, spin coating. The dummy fuller layer 58 may substantially fill the first and second trenches 42 and 44. In addition, the dummy filler layer 58 may include silicon oxide or polysilicon. The silicon oxide or the polysilicon may be formed by means of CVD. The mold insulating layer 40 (i.e., an oxide or other insulator in the mold insulating layer 40) may have a higher density than the silicon oxide of the dummy filler layer 58.

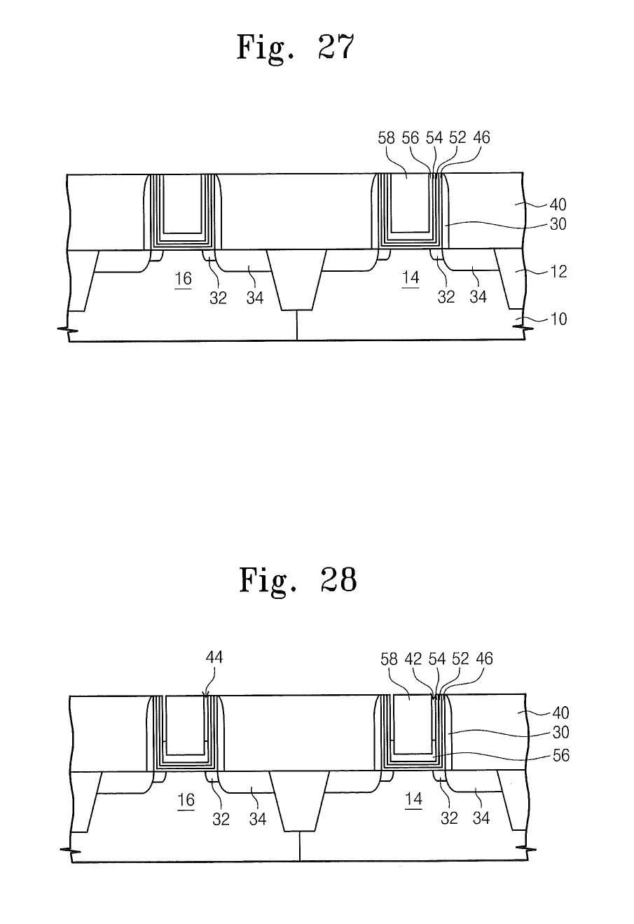

Referring to FIG. 27, the dummy filler layer 58 and the first work function metal layer 56 may be planarized to expose the mold insulating layer 40 (e.g., to expose a surface of the mold insulating layer 40 that is substantially coplanar with a surface of the planarized dummy filler layer 58 and/or the first work function metal layer 56). The planarization of the dummy filler layer 58 and the first work function metal layer 56 may be accomplished by means of an etchback or a CMP. For example, the dummy filler layer 58 of an organic compound may be planarized by means of etchback that includes a dry etch. In addition, the dummy filler layer 58 of silicon oxide or polysilicon may be planarized by means of CMP. Thus, dummy filler layers 58 and first work function metal layers 56 may remain only within the first and second trenches 42 and 44.

Referring to FIG. 28, the first work function metal layers 56 may be removed at the upper portions (e.g., portions farthest from the substrate 10) of the first and second trenches 42 and 44. For example, the first work function metal layers 56 may be recessed at an upper portion of the first and second trenches 42 and 44 between the mold insulating layer 40 and the dummy filler layer 58. Recession of the first work function metal layers 56 may be accomplished by means of a dry etch or a wet etch having an etch selectivity of greater than about two to one with respect to the dummy filler layer 58 and the mold insulating layer 40.

As such, according to some embodiments of methods of manufacturing a MOS transistor, a first work function metal layer 56 may be formed more easily if the first work function metal layer 56 has a smaller thickness on bottom surfaces of first and second trenches 42 and 44 than on upper portions (e.g., portions farther from the substrate 10) of sidewalls of the first and second trenches 42 and 44. The first work function metal layer 56 may be between a mold insulting layer 40 and a dummy filer layer 58. Also, the first work function metal layers 56 in the first and second trenches 42 and 44 may be first work function metal patterns each having a ␣-shaped section. For example, the first work function metal layers 56 may be recessed on the sidewalls of the first and second trenches 42 and 44 to a depth of about 450 angstroms in a thickness ranging from about 100 angstroms to about 300 angstroms.

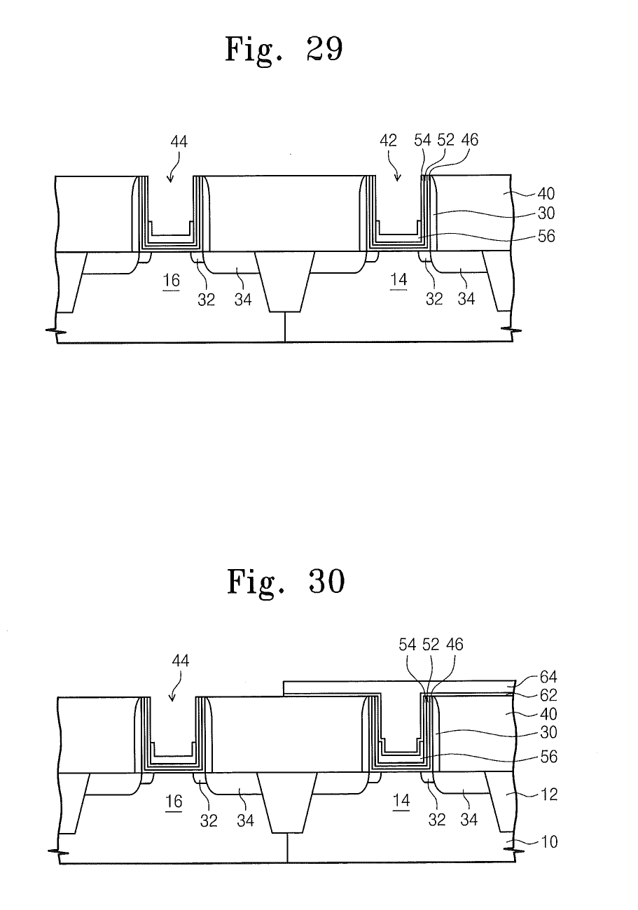

Referring to FIG. 29, the dummy filler layers 58 may be removed from the first trench 42 and the second trench 44. The first work function metal layers 56 may be exposed within the first trench 42 and the second trench 44. Each of the dummy filler layers 58 may be removed by means of ashing, dry etch or wet etch. For example, dummy filler layers 58 of an organic compound may be removed by means of ashing. In addition, dummy filler layers 58 of silicon oxide or polysilicon may be removed by means of dry etch or wet etch. The second barrier metal layers 54 may protect the first barrier metal layers 52 and the gate insulating layers 46 from an etch gas or an etchant during removal of the dummy filler layers 58.

Referring to FIG. 30, a sacrificial oxide layer 62 and a sixth photoresist pattern 64 may be formed on a portion of a surface of the mold insulating layer 40 and within (e.g., within sidewalls of) the first trench 42. The sacrificial oxide layer 62 and the sixth photoresist pattern 64 may be formed to expose the first work function metal layer 56 within the second trench 44. The sacrificial oxide layer 62 may be formed on substantially the entire surface of the substrate 10 (e.g., within the first trench 42 and the second trench 44). The sixth photoresist pattern 64 may be formed on a portion of a surface of the mold insulating layer 40 and within the first trench 42 by means of a photolithography process for a photoresist (not shown) formed on the sacrificial oxide layer 62. The sacrificial oxide layer 62 exposed by the sixth photoresist pattern 64 may be removed by means of dry etch or wet etch. The sacrificial oxide layer 62 may enhance adhesion between the first work function metal layer 56 on the first active layer 14 and the sixth photoresist pattern 64, and between the second barrier metal layer 54 on the first active layer 14 and the sixth photoresist pattern 64.

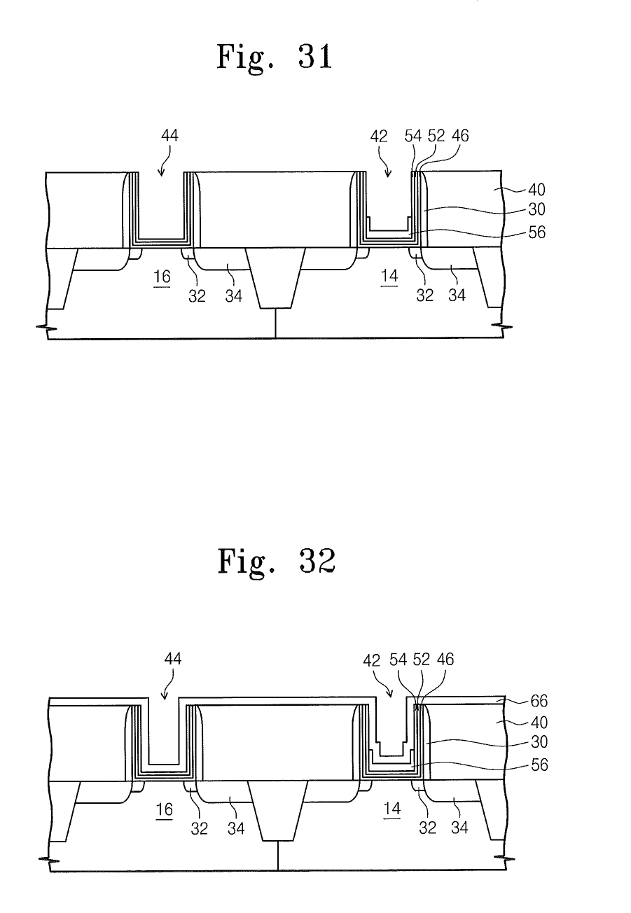

Referring to FIG. 31, the first work function metal layer 56 may be removed from within the second trench 44. The first work function metal layer 56 may be removed from within the second trench 44 by dry etch or wet etch using the sixth photoresist pattern 64 as an etch mask. Afterward, the sacrificial oxide layer 62 and the sixth photoresist pattern 64 may be removed.

Referring to FIG. 32, a second work function metal layer 66 may be formed within the first and second trenches 42 and 44 and on the entire surface of the mold insulating layer 40. The second work function metal layer 66 may have a lower work function than the first work function metal layer 56. The second work function metal layer 66 may include aluminum (Al), tungsten (W), molybdenum (Mo), titanium aluminum (TiAl), titanium tungsten (TiW), titanium molybdenum (TiMo), tantalum aluminum (TaAl), tantalum tungsten (TaW), or tantalum molybdenum (TaMo). For example, titanium aluminum (TiAl) may have a work function that is lower by about 1.0 eV than titanium nitride (TiN) than the first work function metal layer 56. Titanium aluminum (TiAl) may be formed by means of CVD or PVD.

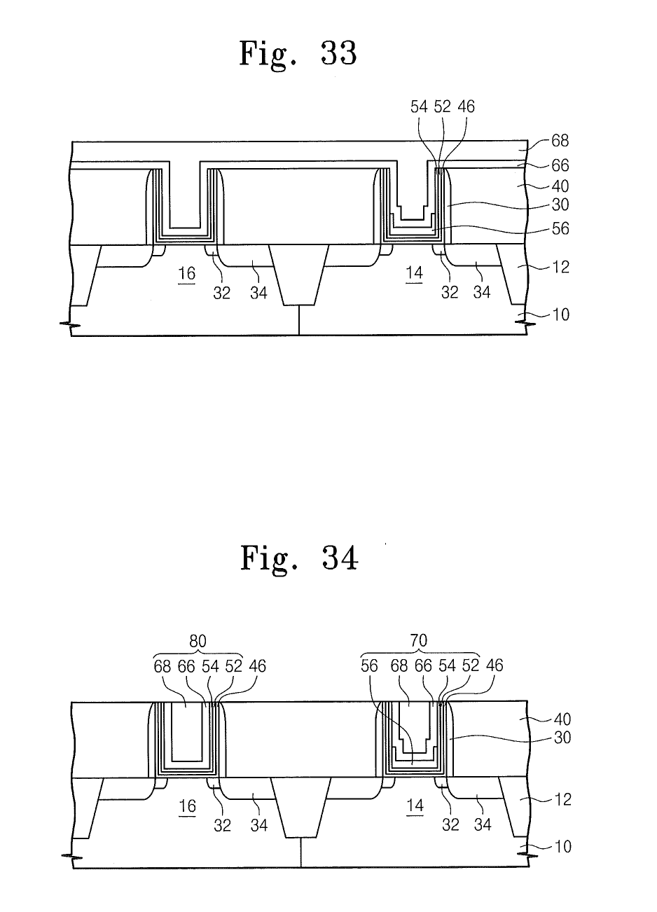

Referring to FIG. 33, a third metal layer 68 may be formed within the first and second trenches 42 and 44 and on the mold insulating layer 40. The third metal layer 68 may be formed by means of PVD or CVD. The third metal layer 68 may include at least one of low-resistance metals such as aluminum (Al), tungsten (W), titanium (Ti), and tantalum (Ta). The third metal layer 68 may be formed within the first trench 42 substantially without formation of voids therein. The second work function metal layer 66 may include a diffusion metal layer through which low-resistance metallic components of the third metal layer 68 may be diffused into the second barrier metal layer 54. Accordingly, the second work function metal layer 66 may be formed by an annealing process for the second barrier metal layer 54 and the third metal layer 68.

Referring to FIG. 34, the third metal layer 68 may be planarized to expose the mold insulating layer 40. A first gate electrode 70 and a second gate electrode 80 may be formed on the first active region 14 and the second active region 16, respectively. The first gate electrode 70 and the second gate electrode 80 may be gate lines extending in a direction that is substantially perpendicular to an arrangement direction of source/drain impurity regions 34 and/or a surface of the substrate 10. The third metal layer 68 may be planarized by means of CMP or etchback. The first gate electrode 70 and the second gate electrode 80 may be separated through the planarization of the third metal layer 68. The first gate electrode 70 and the second gate electrode 80 may have top surfaces of the same height or almost the same height (e.g., surfaces substantially coplanar with an exposed surface of the mold insulating layer 40). The first gate electrode 70 may include a first barrier metal layer 52, a second barrier metal layer 54, a first work function metal layer 56, a second work function metal layer 66, and a third metal layer 68. The first gate electrode 70 may constitute a PMOS transistor in the first active region 14. The second gate electrode 80 may include a second barrier metal layer 52, a second barrier metal layer 54, a second work function metal layer 66, and a third metal layer 68. The second gate electrode 80 may constitute an NMOS transistor in the second active region 16. The first gate electrode 70 and the second gate electrode 80 may each have a length/height of about 450 angstroms (e.g., from a boundary surface with the substrate 10).

In an NMOS transistor, a threshold voltage may decrease when work functions of metal layers on a gate insulating layer 46 are low. The NMOS transistor may include a second gate electrode 80 including a metallic component of a low work function. The second gate electrode 80 may include a first barrier metal layer 52, a second barrier metal layer 54, a second work function metal layer 66, and a third metal layer 68. The second work function metal layer 66 may include the same metal as the third metal layer 68.

In a PMOS transistor, a threshold voltage may decrease when work functions of metal layers on a gate insulating layer 46 are high. The PMOS transistor may include a first gate electrode 70 containing a metallic component of a high work function.

For example, the first gate electrode 70 may include a first barrier metal layer 52, a second barrier metal layer 54, a first work function metal layer 56, a second work function metal layer 66, and a third metal layer 68. If the second gate electrode 80 does not include the second work function metal layer 66, the first gate electrode 70 also may not include the second work function metal layer 66.

Referring to FIGS. 31 and 34, the first work function metal layer 56 may be removed from an upper portion of the first trench 42. The first work function metal layer 56 formed on a sidewall of the first trench 42 may have a lesser thickness than that formed on a bottom surface of the first trench 42. A resistance of a gate line may thus decrease. According to some methods of manufacturing a MOS transistor according to some embodiments, a resistance of a gate line of a PMOS transistor may be reduced/minimized.

Although not shown, the methods of manufacturing a MOS transistor may be completed/finalized by removing a mold insulating layer 40 from a source/drain impurity region 34 to form a contact hole and forming a source/drain electrode in the contact hole.

In some embodiments, (a) a first gate electrode including a first work function metal layer, a second work function metal layer, and a third metal layer, and (b) a second gate electrode including a second work function metal layer and a third metal layer are formed on a first active region and a second active region, respectively. Thus, the first electrode and the second electrode can be formed of metals of different stacked structures. Additionally, because the first gate electrode may include a first work function metal layer having a relatively high work function on the first active region, a threshold voltage of a PMOS transistor can be reduced/minimized. Moreover, because the first work function metal layer can be recessed to be lower than a top surface of a mold oxide layer, a gate line resistance can be reduced/minimized

While the inventive concept has been particularly shown and described with reference to various embodiments thereof, it will be understood by those of ordinary skill in the art that various changes in form and details may be made therein without departing from the spirit and scope of the inventive concept as defined by the following claims. Therefore, the above-disclosed subject matter is to be considered illustrative and not restrictive.

1. A method of manufacturing a MOS transistor, comprising:
providing a substrate including first and second active regions;
forming dummy gate stacks on the first and second active regions;
forming source/drain regions within the first and second active regions adjacent sidewalls of the dummy gate stacks;
forming a mold insulating layer on the source/drain regions;
removing the dummy gate stacks to form a first trench on the first active region and to form a second trench on the second active region;
forming a gate insulating layer in the first and second trenches;
forming first metal patterns within portions of the first and second trenches;
removing the first metal patterns from the second trench while at least portions of the first metal patterns remain within the first trench; and
forming a second metal layer within the first and second trenches to form a first gate electrode on the first active region and to form a second gate electrode on the second active region, the second metal layer formed on the first metal patterns within the first trench.

2. The method of claim 1, wherein each of the first metal patterns includes a first work function metal layer having a higher work function than the second metal layer.

3. The method of claim 1, wherein the first work function metal layer includes titanium nitride.

4. The method of claim 1, further comprising:
after removing the first metal patterns from the second trench, forming a second work function metal layer having a lower work function than the first work function metal layer on the first metal pattern within the first trench, and within the second trench.

5. The method of claim 4, wherein the second work function metal layer includes titanium aluminum.

6. The method of claim 1, wherein forming the first metal patterns comprises:
forming a first metal layer and a dummy filler layer in the first trench and the second trench and on the mold insulating layer;
planarizing the dummy filler layer and the first metal layer to expose a surface of the mold insulating layer;
removing a portion of the first metal layer from between the mold insulating layer and the dummy filler layer to form the first metal pattern at lower portions of the first and second trenches; and
removing the dummy filler layer from the first and second trenches.

7. The method of claim 6, wherein the first metal layer is formed by chemical vapor deposition or atomic layer deposition.

8. The method of claim 1, wherein forming the first metal patterns comprises:
forming a first metal layer that is substantially planar in lower portions of the first and second trenches and on a surface of the mold insulating layer, the first metal layer having a protrusion at upper portions of the first and second trenches such that the first metal layer is thicker at the protrusion than in the lower portions of the first and second trenches;
removing the protrusion of the first metal layer;
forming a dummy filler layer within the first and second trenches and on the mold insulating layer;
planarizing the dummy filler layer and the first metal layer to expose a surface of the mold insulating layer; and
removing the dummy filler layer from the first and second trenches.

9. The method of claim 8, further comprising:
after planarizing the dummy filler layer and the first metal layer, removing portions of the first metal layer from between the mold insulating layer and the dummy filler layer.

10. The method of claim 8, wherein the first metal layer is formed by physical vapor deposition.

11. The method of claim 10, wherein the physical vapor deposition includes sputtering.

12. The method of claim 1, wherein removing the first metal patterns from the second trench comprises:
forming a sacrificial oxide layer on the first metal patterns within the first trench and the second trench;
forming a photoresist pattern on the sacrificial oxide layer within the first trench;
removing the sacrificial oxide layer and the first metal patterns from the second trench; and
after removing the first metal patterns from the second trench, removing the photoresist pattern and the sacrificial oxide layer from the first trench.

13-15. (canceled)

16. A method of manufacturing a MOS transistor, comprising:
forming a mold insulating layer on first and second dummy gates on first and second regions of a substrate;
removing the first and second dummy gates to form first and second trenches between portions of the mold insulating layer;
forming a first metal layer within the first and second trenches;
removing portions of the first metal layer from the first and second trenches to form first metal patterns in the first and second trenches, the first metal patterns having a higher work function than the second metal layer;
removing the first metal patterns from the second trench while at least portions of the first metal patterns remain within the first trench; and
forming a second metal layer within the first and second trenches, the second metal layer formed on the first metal patterns within the first trench, and the second metal layer having a shape within the first trench that is different from a shape of the second metal layer within the second trench.

17. The method of claim 16, wherein forming the first metal patterns comprises:
forming the first metal layer to be substantially planar in lower portions of the first and second trenches and on a surface of the mold insulating layer, the first metal layer having a protrusion at upper portions of the first and second trenches such that the first metal layer is thicker at the protrusion than in the lower portions of the first and second trenches;
removing the protrusion of the first metal layer from sidewalls of the first and second trenches;
forming a dummy filler layer within the first and second trenches and on the mold insulating layer;
planarizing the dummy filler layer and the first metal layer to expose a surface of the mold insulating layer; and
removing the dummy filler layer from the first trench and the second trench.

18. The method of claim 17, further comprising:
after planarizing the dummy filler layer and the first metal layer, removing portions of the first metal layer from between the mold insulating layer and the dummy filler layer to form the first metal patterns, the first metal patterns having narrower portions on opposing sidewalls of each of the first and second trenches than on a bottom surface of the first and second trenches.

19. The method of claim 16, further comprising:
forming a third metal layer on the second metal layer within the first and second trenches, the third metal layer having a shape within the first trench that is different from a shape of the third metal layer within the second trench.

20. The method of claim 16, further comprising:
before forming the first metal layer, forming a gate insulating layer within the first and second trenches, and forming first and second metal barrier layers on the gate insulating layer within the first and second trenches.
